(19) United States
(12) Patent Application Publication
(10) Pub. No.: US 2020/0058978 A1
(43) Pub. Date: Feb. 20, 2020

(54) CIRCUIT BOARD INCLUDING DIRECTIONAL COUPLER WITH POWER AMPLIFIER MODULE

(71) Applicant: MICROELECTRONICS TECHNOLOGY, INC., HSINCHU (TW)

(72) Inventors: MING-CHE LIOU, HSINCHU (TW); SHIN-CHANG CHANG, HSINCHU (TW)

(21) Appl. No.: 16/440,268

(22) Filed: Jun. 13, 2019

Related U.S. Application Data
(60) Provisional application No. 62/719,329, filed on Aug. 17, 2018.

(51) Int. Cl. H01P 5/18; H03F 3/21; H01P 3/08

(52) U.S. Cl. CPC H01P 5/18; H01P 3/081; H03F 3/211

(57) ABSTRACT

The present disclosure provides an output matching pattern of a power amplifier module. The output matching pattern of the power amplifier module includes a first transmission line and a second transmission line. The first transmission line, in a circuit board, is configured for impedance conversion, and is configured to transfer a signal. The second transmission line, in the circuit board, is configured to sample the signal from the first transmission line. The first transmission line and the second transmission line are separate from each other, and extend and trend in the same direction.

### TECHNICAL FIELD

The present disclosure relates to a circuit board and a power amplifier module using the same, and more particularly, to a circuit board including a directional coupler.

### DISCUSSION OF THE BACKGROUND

Directional couplers are most frequently constructed from two coupled transmission lines set close enough together such that energy passing through one is coupled to the other. This technique is favored at microwave frequencies for which transmission line designs are commonly used to implement many circuit elements. The most common form of directional coupler is a pair of coupled transmission lines. Such arrangement can be realized in a number of technologies including coaxial and planar technologies (stripline and microstripline).

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides an output matching pattern of a power amplifier module. The output matching pattern of the power amplifier module includes a first transmission line and a second transmission line. The first transmission line, in a circuit board, is configured for impedance conversion, and configured to transfer a signal. The second transmission line, in the circuit board, is configured to sample the signal from the first transmission line. The first transmission line and the second transmission line are separate from each other, and extend and trend in the same direction.

In some embodiments, the first transmission line and the second transmission line are in combination to form a directional coupler.

In some embodiments, the first transmission line includes a first section and a second section, wherein impedance conversion performed by the first section of the first transmission line is different from that performed by the second section of the first transmission line. The second transmission line includes a first section and a second section. The first section of the second transmission line is configured to couple a signal only from the first section of the first transmission line. The second section of the second transmission line is configured to couple a signal only from the second section of the first transmission line.

In some embodiments, impedances at an input and an output of the first section of the second transmission line and an input and an output of the second section of the second transmission line are the same.

In some embodiments, a distance between the first section of the first transmission line and the first section of the second transmission line is different from a distance between the second section of the first transmission line and the second section of the second transmission line.

In some embodiments, the distance between the first section of the first transmission line and the first section of the second transmission line is shorter than the distance between the second section of the first transmission line and the second section of the second transmission line.

In some embodiments, impedance conversion performed by the first section of the second transmission line is different from impedance conversion performed by the second section of the second transmission line.

In some embodiments, a distance between the first section of the first transmission line and the first section of the second transmission line is different from a distance between the second section of the first transmission line and the second section of the second transmission line.

In some embodiments, the distance between the first section of the first transmission line and the first section of the second transmission line is shorter than the distance between the second section of the first transmission line and the second section of the second transmission line.

Another aspect of the present disclosure provides an output matching pattern of a power amplifier module. The output matching pattern of the power amplifier module includes a first transmission line and a second transmission line. The first transmission line, in a circuit board, is configured for impedance conversion, and is configured to transfer a signal. The first transmission line includes a plurality of sections. The second transmission line, in the circuit board, includes a plurality of sections, wherein the first transmission line and the second transmission line are in combination to form a directional coupler, wherein a quantity of the sections of the first transmission line is equal to a quantity of the sections of the second transmission line.

In some embodiments, the first transmission line includes a first section and a second section. Impedance conversion performed by the first section of the first transmission line is different from that performed by the second section of the first transmission line. The second transmission line includes a first section and a second section. The first section of the second transmission line is configured to couple a signal only from the first section of the first transmission line. The second section of the second transmission line is configured to couple a signal only from the second section of the first transmission line.

In some embodiments, the first section of the first transmission line is connected to the second section of the first transmission line at a first interface, wherein the first section of the second transmission line is connected to the second section of the second transmission line at a second interface, and wherein the first interface aligns with the second interface.

In some embodiments, impedances at an input and an output of the first section of the second transmission line and an input and an output of the second section of the second transmission line are the same.

In some embodiments, a distance between the first section of the first transmission line and the first section of the second transmission line is different from a distance between the second section of the first transmission line and the second section of the second transmission line.

In some embodiments, the distance between the first section of the first transmission line and the first section of the second transmission line is shorter than the distance between the second section of the first transmission line and the second section of the second transmission line.

In some embodiments, impedance conversion performed by the first section of the second transmission line is different from that performed by the second section of the second transmission line.

Another aspect of the present disclosure provides a circuit is board. The circuit board includes an output matching pattern. The output matching pattern includes a first transmission line and a second transmission line. The first transmission line is configured for impedance conversion, and configured to transfer a signal. The second transmission line is configured to sample the signal from the first transmission line. The first transmission line and the second transmission line are separate from each other, and extend and trend in the same direction.

In some embodiments, the first transmission line and the second transmission line are in combination to form a directional coupler.

In some embodiments, the first transmission line includes a first section and a second section. Impedance conversion performed by the first section of the first transmission line is different from that performed by the second section of the first transmission line. The second transmission line includes a first section and a second section. The first section of the second transmission line is configured to couple a signal only from the first section of the first transmission line. The second section of the second transmission line is configured to couple a signal only from the second section of the first transmission line.

In some embodiments, a quantity of sections of the first transmission line is equal to a quantity of sections of the second transmission line.

In the present disclosure, since the power amplifier module is free of a transmission line like a 50-ohm transmission line, and because the operation of sampling the signal is performed with respect to the first transmission line instead of the transmission line like a 50-ohm transmission line, which is eliminated, the power loss resulting from such transmission line is accordingly eliminated. As a result, the power amplifier module is relatively power efficient.

In the comparative power amplifier module, a directional coupler is formed by combination of a second transmission line and a 50-ohm transmission line. A length of the 50-ohm transmission line results in power loss. As a result, the comparative power amplifier module is relatively power inefficient.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description.

FIG. 1 is a top view diagram of a comparative directional coupler of a power amplifier module, in accordance with some embodiments of the present disclosure.

FIG. 2 is a top view diagram of a directional coupler of a power amplifier module, in accordance with some embodiments of the present disclosure.

FIG. 3 is a top view diagram of the directional coupler shown in FIG. 2, which is terminated at its one port, in accordance with some embodiments of the present disclosure.

FIG. 4 is a top view diagram of the directional coupler shown in FIG. 2, which is terminated at its other port, in accordance with some embodiments of the present disclosure.

FIG. 5 is block diagram illustrating first and second transmission lines shown in FIG. 2, in accordance with some embodiments of the present disclosure.

FIG. 6 is a top view diagram of a power amplifier module including a directional coupler, in accordance with some embodiments of the present disclosure.

FIG. 7 is a top view diagram of another power amplifier module including a directional coupler, in accordance with some embodiments of the present disclosure.

FIG. 8 is a flow chart of a method of forming a directional coupler, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

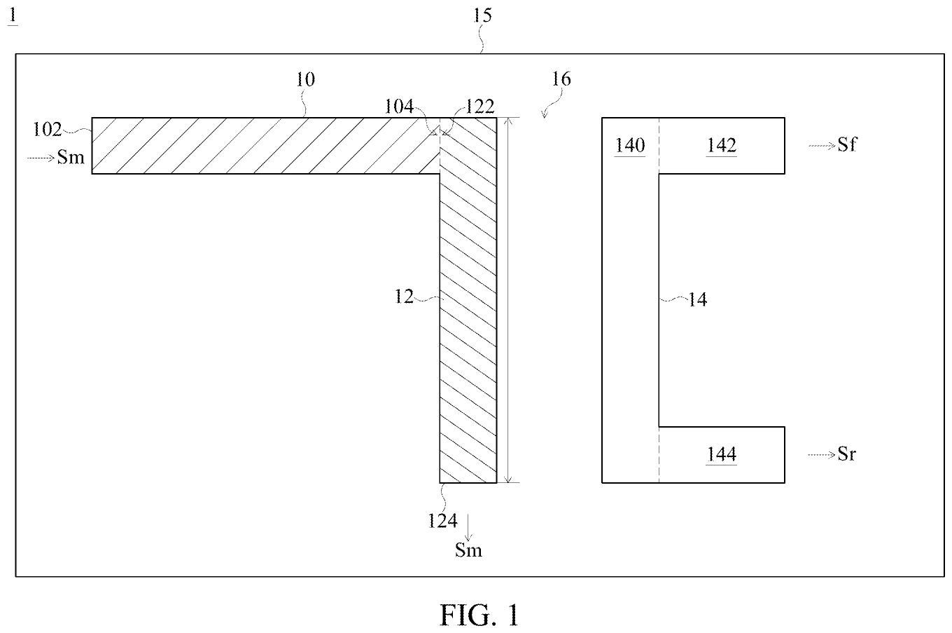

FIG. 1 is a top view diagram of a comparative directional coupler 16 of a power amplifier module 1, in accordance with some embodiments of the present disclosure. Referring to FIG. 1, an output matching pattern of the power amplifier module 1 includes a first transmission line 10, a transmission line 12 with, for example, 50 ohm (hereinafter, the 50-ohm transmission line 12) and a second transmission line 14 in a circuit board 15. In the present embodiment, the transmission line 12 has 50 ohm.

It should be noted that in the following discussion, some values of impedance are described. However, for brevity and clarity, only the real part of the impedance is described when appropriate.

The first transmission line 10 functions to transfer a signal Sm from, for example, a transistor of a power amplifier. Moreover, for impedance matching, the first transmission line 10 functions to convert impedance. In further detail, by way of the first transmission line 10, an impedance of, for example, about 1 ohm at an input 102 of the first transmission line 10 is converted to an impedance of, for example, about 50 ohm at an output 104 of the first transmission line 10. The impedance of 50 ohm serves only as an example, and the converted to impedance may include other suitable values, depending on the application for which the power amplifier module 10 is intended.

The 50-ohm transmission line 12, interfacing with the first transmission line 10, serves a routing function and provides the signal Sin, received from the first transmission line 10, to an antenna, a load, or other devices external to the power amplifier module 1. Moreover, the 50-ohm transmission line 12 substantially does not perform any operation related to impedance conversion. In further detail, an impedance at an input 122 of the 50-ohm transmission line 12 is about, for example, 50 ohm, equal to that at the output 104 of the first transmission line 10, and an impedance at an output 124 of the 50-ohm transmission line 12 is still kept at about, for example, 50 ohm.

The second transmission line 14, for measurement, functions to sample the signal Sm on the 50-ohm transmission line 12 by coupling the signal Sm from the 50-ohm transmission line 12.

As previously mentioned, impedances at both the input 122 and the output 124 of the 50-ohm transmission line 12 are about, for example, 50 ohm. To be relatively accurate in sampling the signal Sm on the 50-ohm transmission line 12, one possible approach is to design impedances at both input and output of the second transmission line 14 are also about, for example, 50 ohm, such that the impedances at the input and the output of the second transmission line 14 are equal to those at the input 122 and the output 124 of the 50-ohm transmission line 12. That is, an impedance characteristic exhibited by the 50-ohm transmission line 12 is the same as that exhibited by the second transmission line 14. Consequently, the second transmission line 14 and the 50-ohm transmission line 12 in combination form a symmetrical directional coupler.

Some relevant electrical characteristics of the signal Sm are substantially the same as those of the coupled signal on the second transmission line 14. As a result, the relevant electrical characteristics of the signal Sm are able to be obtained through analysis of the coupled signal.

The second transmission line 14 includes a body 14, and two ports 142 and 144. The body 14 functions to couple the signal Sm. The port 142 functions to output the sampled forward signal Sf. The port 144 functions to output the sampled reverse signal Sr. Sizes of the ports 142 and 144 shown in FIG. 1 are exaggerated for clarity of illustration.

To accomplish sampling of the signal Sm, a length of the second transmission line 14 must satisfy the following expression:

L=¼λ

where L represents the length of the second transmission line 14, in particular the body 14, and λ represents a wavelength of the signal Sm.

For example, the length of the second transmission line 14 is about 2.5 cm. Due to the limitation of the length of the second transmission line 14, a length of the 50-ohm transmission line 12 also has to be, for example, about 2.5 cm. The 2.5 cm length of the 50-ohm transmission line 12 leads to power loss. For example, power at the output 104 of the first transmission line 10 is about 250 W. However, due to the 2.5 cm length of the 50-ohm transmission line 12, power at the output 124 of the 50-ohm transmission line 12 is only 240 W. Such power loss is an adverse effect, and is required to be alleviated, or even eliminated.

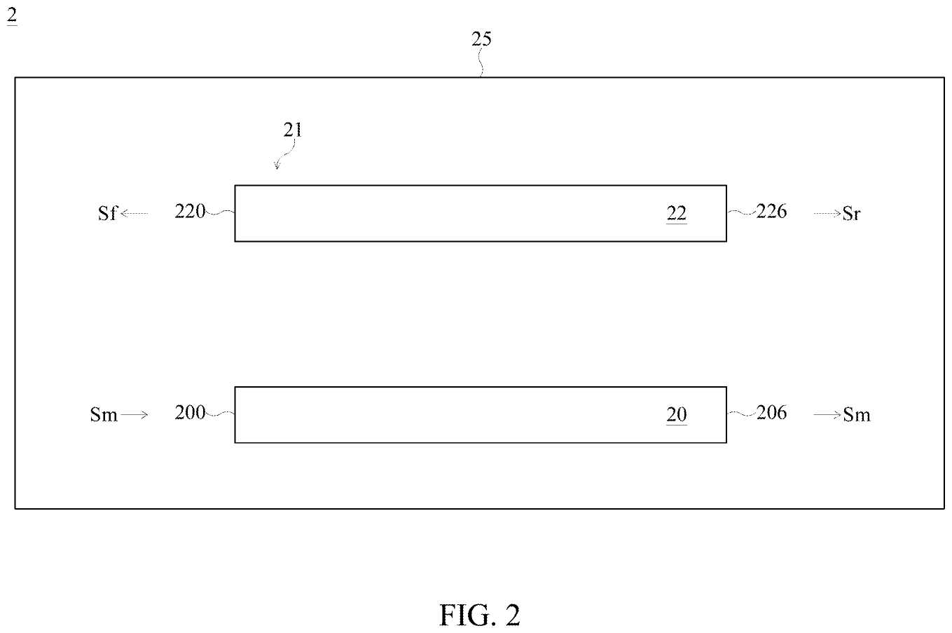

FIG. 2 is a top view diagram of a directional coupler 21 of a power amplifier module 2, in accordance with some embodiments of the present disclosure. Referring to FIG. 2, an output matching pattern of the power amplifier module 2 is similar to the that of the power amplifier module 1 described and illustrated with reference to FIG. 1 except that, for example, the power amplifier module 2 is free of a transmission line, like the 50-ohm transmission line 12 shown in FIG. 1. Moreover, the directional coupler 21 is similar to the directional coupler 16 described and illustrated with reference to FIG. 1 except that, for example, the formation of the directional coupler 21 as will be described in detail below. The directional coupler 21 is formed by a combination of a first transmission 20 and a second transmission line 22 in a circuit board 25. The first transmission line 20 and the second transmission line 22 are separate from each other, and extend and trend in the same direction.

The first transmission line 20 functions to receive a signal Sin at its input 200, and provides the signal Sm at its output 206 to an antenna, a load, or other devices external to the power amplifier module 2. The first transmission line 20 is similar to the first transmission line 10 described and illustrated with reference to FIG. 1. Therefore, detailed descriptions of similar features are omitted herein. In some embodiments, the circuit board 25 includes a printed circuit board (PCB).

The second transmission line 22 is similar to the second transmission line 14 described and illustrated with reference to FIG. 1 except that, for example, the second transmission line 22 is arranged immediately adjacent to the first transmission line 20. Accordingly, the second transmission line 22 samples the signal Sm from the first transmission line 20 by coupling the signal Sm on the first transmission line 20. That is, the second transmission line 22 and the first transmission line 24 in combination form a directional coupler. In particular, because the first transmission line 20 functions to convert impedance and therefore has different impedances at its input 200 and output 206, the first transmission line 20 and the second transmission line 22 in combination form an asymmetric directional coupler.

Moreover, as previously mentioned, since the power amplifier module 2 is free of a transmission line like the 50-ohm transmission line 12 shown in FIG. 1, the nonexistent transmission line and the second transmission line 22 do not form any directional coupler.

In order for the second transmission line 22 to couple the signal Sm from the first transmission line 20, the second transmission line 22 must satisfy the following equation:

L=¼λ

Where L represents a length of the second transmission line 22, and 2 represents a wavelength of the signal Sm.

In summary, the length L of the second transmission line 22 is a function of the wavelength of the signal Sm.

In the present disclosure, since the power amplifier module 2 is free of a transmission line like the 50-ohm transmission line 12, and because the operation of sampling the signal Sm is performed with respect to the first transmission line 20 instead of the transmission line like the 50-ohm transmission line, which is eliminated, the power loss resulting from such transmission line is accordingly eliminated. As a result, the power amplifier module 2 is relatively power efficient. Moreover, because of the arrangement of the first transmission line 20 and the second transmission line, simulation results reflect a fact in which directivity of the directional coupler 21 is relatively good.

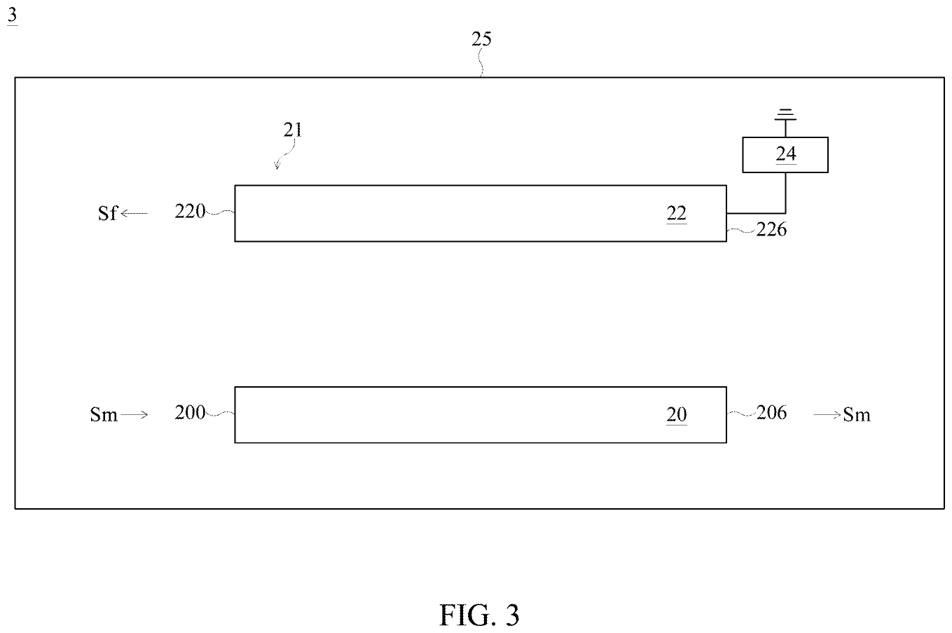

FIG. 3 is a top view diagram of the directional coupler 21 shown in FIG. 2, in which the directional coupler 21 is terminated at its one port 226, in accordance with some embodiments of the present disclosure. Referring to FIG. 3, if only the sampled forward signal Sf is required to be analyzed, an impedance device 24 is arranged to couple a port 226 of the second transmission line 22 to a reference ground. Moreover, for convenience, a symbol representing the reference ground is depicted in the circuit board 25 shown in FIG. 3.

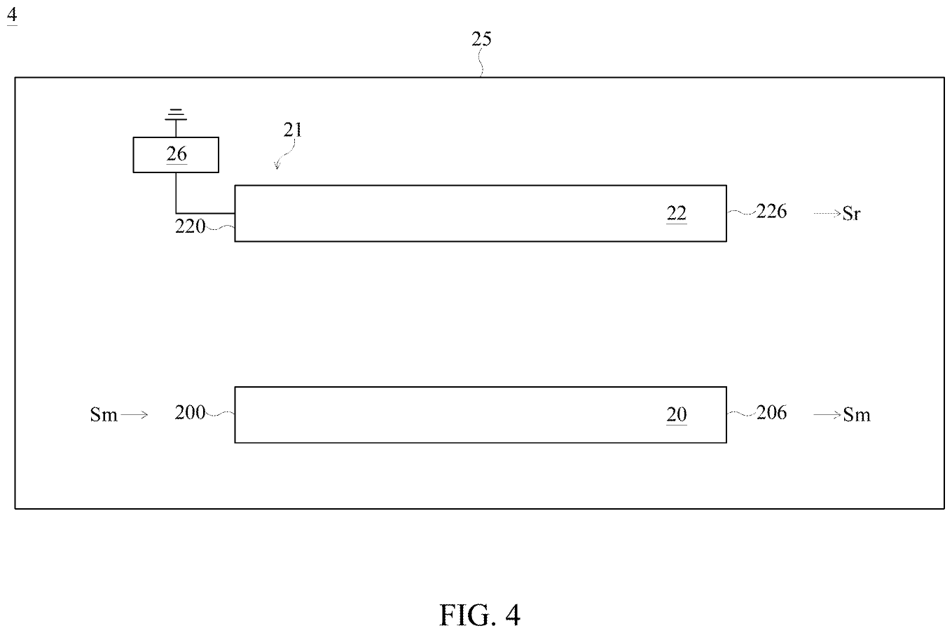

FIG. 4 is a top view diagram of the directional coupler 21 shown in FIG. 2, wherein the directional coupler 21 is terminated at its other port 220, in accordance with some embodiments of the present disclosure. Referring to FIG. 4, if only the sampled reverse signal Sr is required to be analyzed, an impedance device 26 is arranged to couple the port 220 of the second transmission line 22 to the reference ground. It should be noted that since the directional coupler 21 includes an asymmetric directional coupler, an impedance value of the impedance device 26 may be different from that of the impedance device 24 shown in FIG. 3. Moreover, for convenience, a symbol representing the reference ground is depicted in the circuit board 25 shown in FIG. 4.

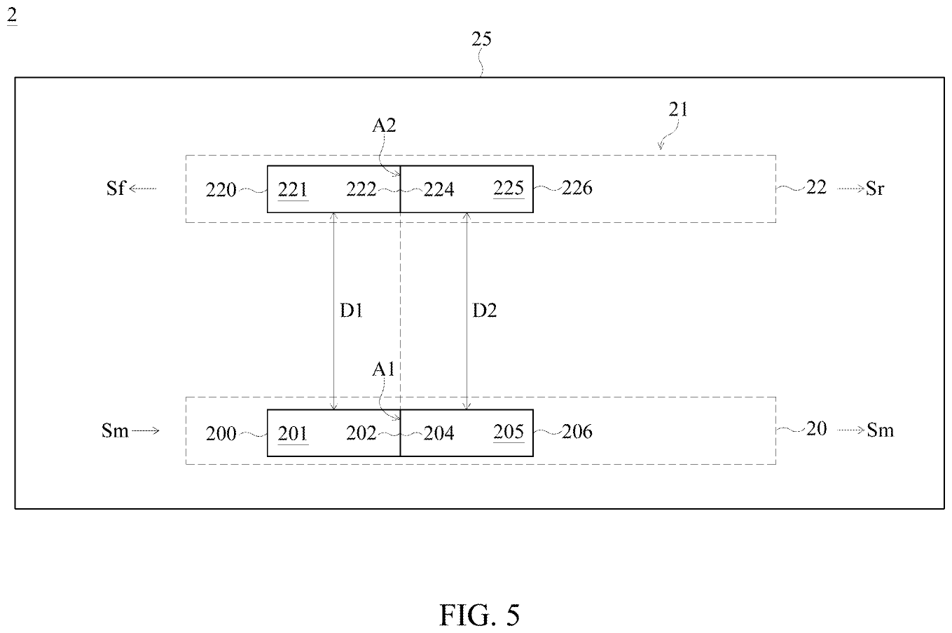

FIG. 5 is block diagram illustrating the first and second transmission lines 20 and 22 shown in FIG. 2, in accordance with some embodiments of the present disclosure.

Referring to FIG. 5, the first transmission line 20 includes a plurality of sections. Each of the sections may perform different impedance conversions. For brevity and clarity, only two first and second sections 201 and 205 of the sections are depicted. However, the present disclosure is not limited to any quantities.

The first section 201 functions to convert impedance. The first section 201 is a beginning stage of the first transmission line 20, and the input 200 serves as an input of the first section 201 of the first transmission line 20. In addition to the input 200, the first section 201 has an output 206. However, such arrangement serves only as an example, and the present disclosure is not limited thereto. The first section 201 may be the middle stage of the first transmission line 20.

The second section 205, interfacing with the first section 201 of the first transmission line 20, is an end stage of the first transmission line 20, and the output 206 serves as an output of the second section 205 of the first transmission line 20. In addition to the output 205, the second section 205 has an input 204, which interfaces with the output 202 of the first section 201. Moreover, the second section 205 functions to perform an impedance conversion different from the impedance conversion performed by the first section 201. For example, referring to the impedance conversion of the first section 201, an impedance of, for example, 1 ohm at its input 200 is converted to an impedance of, for example, 30 ohm at its output 202. Subsequently, referring to the impedance conversion of the second section 205, an impedance of, for example, 30 ohm at its input 204 is converted to an impedance of, for example, 50 ohm at its output 206.

The second transmission line 22 includes a plurality of sections. Each of the sections may perform different impedance conversions. For brevity and clarity, only two first and second sections 221 and 225 of the sections are depicted. However, the present disclosure is not limited to any quantities.

The first section 221, immediately adjacent to the first section 201 of the first transmission line 20, functions to couple a signal only on the first section 201 of the first transmission line 20.

The second section 225, immediately adjacent to the second section 205 of the first transmission line 20, functions to couple a signal only on the second section 205 of the first transmission line 20.

In the present disclosure, the individual section of the second transmission line 22 is responsible for a signal on an individual section of the first transmission line 20. Therefore, some relevant electrical characteristics of the coupled signal provided by the second transmission line 22 are able to relatively accurately reflect electrical characteristics of the signal Sm. As a result, a measurement or simulation based on the coupled signal is relatively accurate.

In some embodiments, impedance conversions performed by the first and second sections 221 and 225 of the second transmission line 22 are the same. In further detail, for example, impedances at both the input and output 220 and 222 of the first section 221 are about, for example, 50 ohm. Also, impedances at both the input and output 224 and 226 of the second section 225 are about, for example, 50 ohm. Impedance from the input 220 to the output 226 of the second transmission line 226 is kept unchanged. In such embodiment, design and implementation of the second transmission line 22 are relatively simple.

In some embodiments, impedance conversions performed by the first and second sections 221 and 225 of the second transmission line 22 are the same. Moreover, to batter sense the signal Sm, a distance D1 between the first section 201 and the first section 221 is different from, and in particular shorter than, a distance D2 between the second section 205 and the second section 225. In such embodiment, some relevant electrical characteristics of the coupled signal provided by the second transmission line 22 are able to relatively accurately reflect electrical characteristics of the signal Sm. As a result, a measurement or simulation based on the coupled signal is relatively accurate.

In some embodiments, the first section 221 performs an impedance conversion different from the impedance conversion performed by the second section 225. In further detail, for example, referring to the impedance conversion of the first section 221, an impedance of, for example, 10 ohm at its input 220 is converted to an impedance of, for example, 30 ohm at its output 222. Next, referring to the impedance conversion of the second section 225, an impedance of, for example, 30 ohm at its input 224 is converted to an impedance of 50 ohm at its output 226. In such embodiment, some relevant electrical characteristics of the coupled signal provided by the second transmission line 22 are able to relatively accurately reflect electrical characteristics of the signal Sm. As a result, a measurement or simulation based on the coupled signal is relatively accurate.

In some embodiments, impedance conversions performed by the first section 221 and the second section 225 of the second transmission line 22 are different from each other. Moreover, to batter sense the signal Sm, the distance D1 between the first section 201 and the first section 221 is different from, and in particular shorter than, the distance D2 between the second section 205 and the second section 225. In such embodiment, some relevant electrical characteristics of the coupled signal provided by the second transmission line 22 are able to relatively accurately reflect electrical characteristics of the signal Sm. As a result, a measurement or simulation based on the coupled signal is relatively accurate.

In some embodiments, within the first transmission line 20, the first section 201 is connected to the second section 205 at a first interface A1. Within the second transmission line 22, the first section 221 is connected to the second section 225 at a second interface A2. The first interface A1 aligns with the second interface A2. In summary, for the second transmission line 22, there are one or more interfaces to align with one or more interfaces of the first transmission line 20. That is, a quantity of the sections of the first transmission line 20 is equal to a quantity of the sections of the second transmission line 22. Accordingly, some relevant electrical characteristics of the coupled signal provided by the second transmission line 22 are able to relatively accurately reflect electrical characteristics of the signal Sm. As a result, a measurement or simulation based on the coupled signal is relatively accurate.

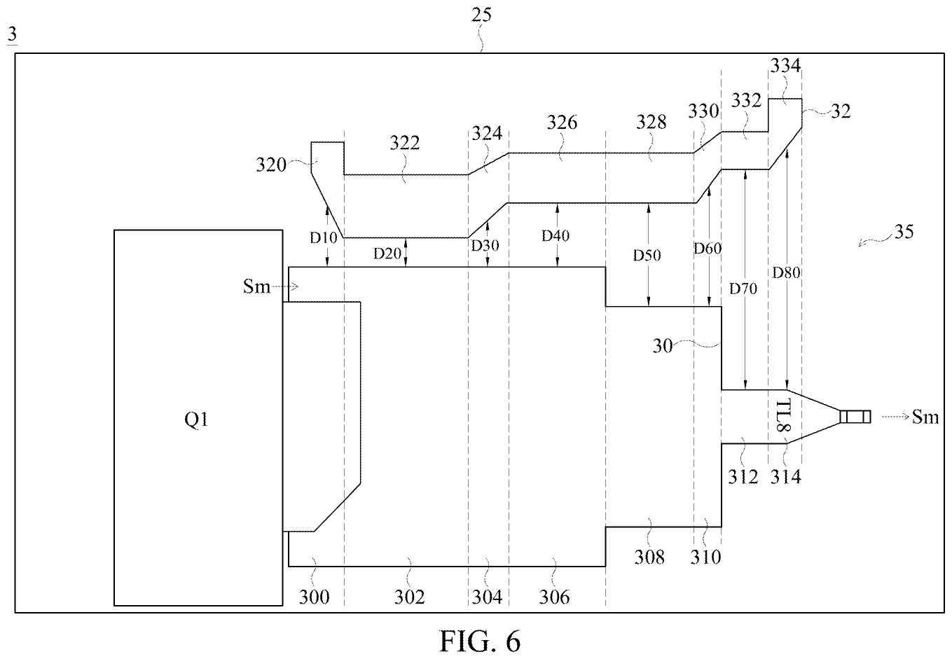

FIG. 6 is a top view diagram of a power amplifier module 3 including a directional coupler 35, in accordance with some embodiments of the present disclosure. Referring to FIG. 6, in addition to the directional coupler 35, the power amplifier module 3 includes a transistor Q of a power amplifier functioning to provide a signal Sm to the directional coupler 35. The directional coupler 35 is defined by a combination of a first transmission line 30 and a second transmission line 32.

The first transmission line 30 includes a plurality of sections 300, 302, 304, 306, 308, 310, 312 and 314, wherein impedance conversion performed by one of the sections 302 to 314 is different from impedance conversion performed by at least another one of the sections 302 to 314. Functions of the first transmission line 30 and the sections thereof are the same as functions of the first transmission line 20 and the sections 201 and 205 thereof. Therefore, the detailed descriptions are omitted herein.

The second transmission line 32 includes a plurality of sections 320, 322, 324, 326, 328, 330, 332 and 334, wherein impedance conversion performed by one of the sections 320 to 334 is different from impedance conversion performed by at least another one of the sections 320 to 334. For example, referring to impedance conversion performed by the section 320, impedances at its input and output are 10 ohm and 70 ohm, respectively, while referring to impedance conversion performed by the section 322, impedances at its input and output are 70 ohm and 150 ohm, respectively. Accordingly, some relevant electrical characteristics of the coupled signal provided by the second transmission line 32 are able to relatively accurately reflect electrical characteristics of the signal Sm. As a result, a measurement or simulation based on the coupled signal is relatively accurate.

Moreover, the section 300 of the first transmission line 30 and the section 320 of the second transmission line 32 are spaced apart by a distance D10. Similarly, the remaining sections 302 to 314 of the first transmission line 32 and the remaining sections 322 to 334 of the second transmission line 32 are spaced apart by distances D20, D30, D40, D50, D60, D70 and D80, respectively. In some embodiments, one of the distances D10 to D80 may be different from at least one another of the distances D10 to D80.

In addition, as previously mentioned, the first transmission line 20 and the second transmission line 22 extend and trend in the same direction. In some embodiments, the extension and trend in the same direction refers to that at least one section of the first transmission line 20 is parallel to the corresponding section of the second transmission line 22. For example, the section 322 of the first transmission line 20 is parallel to the corresponding section 302 of the second transmission line 22.

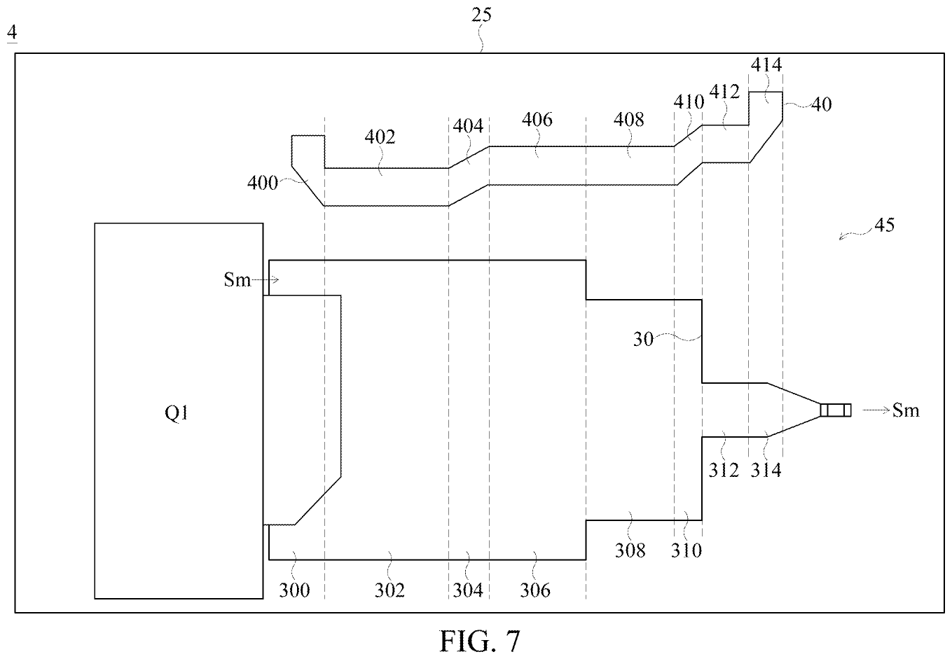

FIG. 7 is a top view diagram of another power amplifier module 4 including a directional coupler 45, in accordance with some embodiments of the present disclosure. Referring to FIG. 7, the directional coupler 45 is similar to the directional coupler 35 described and illustrated with reference to FIG. 6 except that, for example, the directional coupler 45 includes a second transmission line 40 including a plurality of sections 400, 402, 404, 406, 408, 410, 412 and 414.

Impedance conversions performed by each of the sections 400 to 414 of the second transmission line 22 are the same. For example, impedances at both input and output of the section 400 are about, for example, 50 ohm, while impedances at both input and output of the section 402 are also about 50 ohm. Impedance from an input to an output of the second transmission line 40 is kept unchanged.

In design of a directional coupler, at least a distance between two transmission lines and impedance conversion performed by a section of each of the two transmission lines are both factors that determine whether relevant characteristics of a coupled signal are able to accurately reflect corresponding electrical characteristics of the signal Sm.

In the present embodiment, since the factor of the impedance conversion is kept constant, design and implementation of the second transmission line 22 are relatively simple.

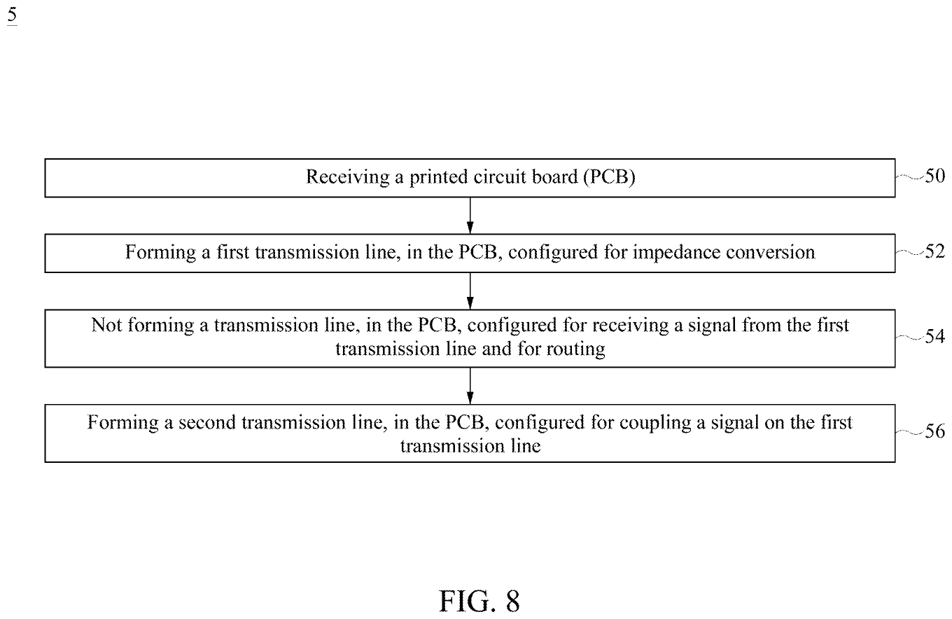

FIG. 8 is a flow chart of a method 5 of forming a directional coupler, in accordance with some embodiments of the present disclosure. Referring to FIG. 8, the method 5 includes operations 50, 52, 54 and 56

The method 5 begins with operation 50, in which a printed circuit board (PCB) is received.

The method 5 continues with operation 52, in which a first transmission line configured for impedance conversion is formed in the PCB.

The method 5 continues with operation 54, in which a transmission line configured for transferring a signal from the first transmission line and for routing is not formed in the PCB.

The method 5 proceeds to operation 56, in which a second transmission line configured for coupling the signal from the first transmission line is formed in the PCB. The second transmission line and the first transmission line are separate from each other, and extend and trend in the same direction.

The method 5 is merely an example, and is not intended to limit the present disclosure beyond what is explicitly recited in the claims. Additional operations can be provided before, during, and after the method 5, and some operations described can be replaced, eliminated, or moved around for additional embodiments of the method.

In the present disclosure, since the power amplifier module 2 is free of a transmission line like a 50-ohmn transmission line and because the operation of sampling the signal Sm is performed with respect to the first transmission line 20 instead of the transmission line like the 50-ohm transmission line, which is eliminated, the power loss resulting from such transmission line is accordingly eliminated. As a result, the power amplifier module 3 is relatively power efficient.

In the comparative power amplifier module 1, the directional coupler 16 is formed by combination of the second transmission line 14 and the 50-ohm transmission line 12. A length of the 50-ohm transmission line 12 results in power loss. As a result, the comparative power amplifier module 1 is relatively power inefficient.

One aspect of the present disclosure provides an output matching pattern of a power amplifier module. The output matching pattern of the power amplifier module includes a first transmission line and a second transmission line. The first transmission line, in a circuit board, is configured for impedance conversion, and is configured to transfer a signal. The second transmission line, in the circuit board, is configured to sample the signal from the first transmission line. The first transmission line and the second transmission line are separate from each other, and extend and trend in the same direction.

Another aspect of the present disclosure provides an output matching pattern of a power amplifier module. The output matching pattern of the power amplifier module includes a first transmission line and a second transmission line. The first transmission line, in a circuit board, is configured for impedance conversion, and is configured to transfer a signal. The first transmission line includes a plurality of sections. The second transmission line, in the circuit board, includes a plurality of sections, wherein the first transmission line and the second transmission line in combination form a directional coupler, and wherein a quantity of the sections of the first transmission line is equal to a quantity of the sections of the second transmission line.

Another aspect of the present disclosure provides a circuit board. The circuit board includes an output matching pattern. The output matching pattern includes a first transmission line and a second transmission line. The first transmission line is configured for impedance conversion, and configured to transfer a signal. The second transmission line is configured to sample the signal from the first transmission line. The first transmission line and the second transmission line are separate from each other, and extend and trend in the same direction.

The scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A power amplifier module, comprising:
an output matching pattern, comprising:
a first transmission line, in a circuit substrate, configured for impedance conversion, and configured to transfer a signal; and
a second transmission line, in the circuit substrate, configured to sample the signal from the first transmission line,
wherein the first transmission line and the second transmission line are separate from each other, and extend and trend in the same direction.

2. The power amplifier module of claim 1, wherein the first transmission line and the second transmission line are in combination to form a directional coupler.

3. The power amplifier module of claim 1,
wherein the first transmission line includes:
a first section; and
a second section, wherein impedance conversion performed by the first section of the first transmission line is different from that performed by the second section of the first transmission line, and
wherein the second transmission line includes:
a first section configured to couple a signal only from the first section of the first transmission line; and
a second section configured to couple a signal only from the second section of the first transmission line.

4. The power amplifier module of claim 3, wherein impedances at an input and an output of the first section of the second transmission line and an input and an output of the second section of the second transmission line are the same.

5. The power amplifier module of claim 4, wherein a distance between the first section of the first transmission line and the first section of the second transmission line is different from a distance between the second section of the first transmission line and the second section of the second transmission line.

6. The power amplifier module of claim 5, wherein the distance between the first section of the first transmission line and the first section of the second transmission line is shorter than the distance between the second section of the first transmission line and the second section of the second transmission line.

7. The power amplifier module of claim 3, wherein an impedance conversion performed by the first section of the second transmission line is different from that performed by the second section of the second transmission line.

8. The power amplifier module of claim 7, wherein a distance between the first section of the first transmission line and the first section of the second transmission line is different from a distance between the second section of the first transmission line and the second section of the second transmission line.

9. The power amplifier module of claim 8, wherein the distance between the first section of the first transmission line and the first section of the second transmission line is shorter than the distance between the second section of the first transmission line and the second section of the second transmission line.

10. A power amplifier module, comprising:
an output matching pattern, comprising:
a first transmission line, in a circuit board, configured for impedance conversion, and configured to transfer a signal, wherein the first transmission line includes a plurality of sections; and
a second transmission line, in the circuit board, including a plurality of sections, wherein the first transmission line and the second transmission line are in combination to form a directional coupler,
wherein a quantity of the sections of the first transmission line is equal to a quantity of the sections of the second transmission line.

11. The power amplifier module of claim 10,
wherein the first transmission line includes:
a first section; and
a second section, wherein an impedance conversion performed by the first section of the first transmission line is different from that performed by the second section of the first transmission line, and
wherein the second transmission line includes:
a first section configured to couple a signal only from the first section of the first transmission line; and
a second section configured to couple a signal only from the second section of the first transmission line.

12. The power amplifier module of claim 11,
wherein the first section of the first transmission line is connected to the second section of the first transmission line at a first interface, and
wherein the first section of the second transmission line is connected to the second section of the second transmission line at a second interface,
wherein the first interface aligns with the second interface.

13. The power amplifier module of claim 11, wherein impedances at an input and an output of the first section of the second transmission line and an input and an output of the second section of the second transmission line are the same.

14. The power amplifier module of claim 13, wherein a distance between the first section of the first transmission line and the first section of the second transmission line is different from a distance between the second section of the first transmission line and the second section of the second transmission line.

15. The power amplifier module of claim 14, wherein the distance between the first section of the first transmission line and the first section of the second transmission line is shorter than the distance between the second section of the first transmission line and the second section of the second transmission line.

16. The power amplifier module of claim 11, wherein an impedance conversion performed by the first section of the second transmission line is different from that performed by the second section of the second transmission line.

17. A circuit board, comprising:
an output matching pattern, comprising:
a first transmission line configured for impedance conversion, and configured to transfer a signal; and
a second transmission line configured to sample the signal from the first transmission line,
wherein the first transmission line and the second transmission line are separate from each other, and extend and trend in the same direction.

18. The circuit board of claim 17, wherein the first transmission line and the second transmission line are in combination to form a directional coupler.

19. The circuit board of claim 17,
wherein the first transmission line includes:
a first section; and
a second section, wherein impedance conversion performed by the first section of the first transmission line is different from that performed by the second section of the first transmission line, and
wherein the second transmission line includes:
a first section configured to couple a signal only from the first section of the first transmission line; and
a second section configured to couple a signal only from the second section of the first transmission line.

20. The circuit board of claim 17, wherein a quantity of sections of the first transmission line is equal to a quantity of sections of the second transmission line.
